(19) United States
(12) Patent Application Publication
(10) Pub. No.: US 2025/0347721 A1
(43) Pub. Date: Nov. 13, 2025

(54) CLOSED LOOP, HIGH ACCURACY HALL EFFECT SENSOR AFE WITH AUTOZEROED SWITCHED-CAPACITOR ANALOG ACCUMULATOR

(71) Applicant: STMicroelectronics International N.V., Geneva (CH)

(72) Inventors: Francesco BORGIOLI, Livorno (IT); Roberto Pio BAORDA, Casarile (IT); Paolo ANGELINI, Bologna (IT); Danilo Karim KADDOURI, Pero (MI) (IT); Lorenzo ERCOLINI, Milano (IT)

(73) Assignee: STMicroelectronics International N.V., Geneva (CH)

(21) Appl. No.: 19/277,743

(22) Filed: Jul. 23, 2025

Related U.S. Application Data
(63) Continuation of application No. 18/367,044, filed on Sep. 12, 2023, now Pat. No. 12,399,197.

(51) Int. Cl. G01R 15/20; G01R 19/10

(52) U.S. Cl. CPC G01R 15/202; G01R 19/10

(57) ABSTRACT

Disclosed herein is a method of measuring an input current using an analog front-end. The method includes driving an input inductor with the input current to produce an input magnetic field, driving a self-test inductor with a known self-test current to produce a self-test magnetic field, and alternately extracting differential voltages proportional to the input magnetic field and the self-test magnetic field via a Hall effect sensor circuit and an extraction circuit. In addition, the method includes sampling and holding the differential voltage proportional to the self-test magnetic field, generating an error voltage by subtracting a reference voltage from the held differential voltage proportional to the self-test magnetic field, integrating the error voltage over time to produce a calibration signal, and calibrating the Hall effect sensor circuit using the calibration signal to drive the error voltage toward zero.

### RELATED APPLICATION

This is a continuation of U.S. patent application Ser. No. 18/367,044, filed on Sep. 12, 2023, the contents of which are incorporated by reference in their entirety.

### TECHNICAL FIELD

This disclosure is directed to an analog front end for sensing current through a Hall effect sensor. The analog front end is able to compensate the sensitivity of the Hall effect sensor for variation due to temperature and stress.

### BACKGROUND

A Hall effect sensor is a transducer that responds to a magnetic field by varying its output voltage. This sensor operates by energizing a thin strip of conductive material with an electrical current. When subjected to a magnetic field perpendicular to the direction of the current flow, the magnetic field deflects the path of the charge carriers to one side of the material. This deflection leads to a voltage difference across the strip's opposite edges, referred to in the art as the Hall voltage, which is directly proportional to the strength of the magnetic field. This voltage is then measured, amplified, and output in either analog or digital form.

Hall effect sensors may present variability in their sensitivity, which can result in inconsistencies and inaccuracies in their output. The causes of this variability could include temperature changes, manufacturing variances, aging, and supply voltage instability. Given this, compensation techniques have been developed.

For example, temperature and stress on the sensor may be measured and digitized, and then the sensitivity of the sensor may be compensated in an open loop fashion through a digital signal processor; however, the efficiency of the compensation is dependent on the accuracy of the measures of temperature and stress, and such accuracy may be dubious. As another example, an analog front-end with continuous gain calibration biased in current is utilized, necessitating a complex and space consuming design that includes two high-accuracy analog to digital converters (ADCs) and a digital to analog converter (DAC). The digital feedback utilized for gain and offset correction can lead to accuracy challenges. Furthermore, the separation of signal, offset, and reference via frequency domain modulation and demodulation utilized with such approaches results in a trade-off between reference amplitude and system output dynamics, and can cause accuracy problems especially with non-linear or high bandwidth input signals.

Further development is needed to overcome these challenges.

### SUMMARY

A method of measuring an input current uses an analog front-end. An input inductor is driven with the input current to produce an input magnetic field. A self-test inductor is driven with a known self-test current to produce a self-test magnetic field. Differential voltages proportional to the input magnetic field and the self-test magnetic field are alternately extracted via a Hall effect sensor circuit and an extraction circuit. The differential voltage proportional to the self-test magnetic field is sampled and held. An error voltage is generated by subtracting a reference voltage from the held differential voltage proportional to the self-test magnetic field. The error voltage is integrated over time to produce a calibration signal. The Hall effect sensor circuit is calibrated using the calibration signal to drive the error voltage toward zero.

The method may further include sampling and holding the differential voltage proportional to the input magnetic field. The held differential voltage proportional to the input magnetic field may be filtered to thereby produce an output voltage proportional to the input current. The error voltage may be integrated in an analog integrator. Calibrating the Hall effect sensor circuit may force the held differential voltage proportional to the self-test magnetic field to match the reference voltage. Alternately extracting the differential voltages may include reconfiguring interconnections of four Hall effect sensors of the Hall effect sensor circuit so that, in a first phase, their outputs combine to yield the self-test magnetic field, and in a second phase, their outputs combine to yield the input magnetic field. The four Hall effect sensors may be positioned such that external magnetic field contributions cancel when their outputs are combined during the extraction.

A system for measuring an input current includes a Hall effect sensor circuit configured to produce differential voltage outputs based on magnetic fields around an input inductor and a self-test inductor. An input and self-test extraction circuit is configured to alternatingly output a differential voltage indicative of magnetic fields around the input inductor and the self-test inductor. An amplifier is configured to amplify the differential voltages output by the input and self-test extraction circuit. A first sample/hold circuit is configured to sample output of the amplifier when that output is indicative of the magnetic field around the self-test inductor. An integrator circuit is configured to calibrate the Hall effect sensor circuit based upon on an error between the output sampled by the first sample/hold circuit and a reference voltage.

The system may further include a second sample/hold circuit configured to sample the output of the amplifier when that output is indicative of the magnetic field around the input inductor. A low-pass filter may be coupled to the output of the second sample/hold circuit to produce a measurement voltage proportional to the input current. The integrator circuit may include an analog subtraction stage configured to subtract the reference voltage from the output of the first sample/hold circuit to generate an error voltage representative of the error. The integrator circuit may further include an integrating element that integrates the error voltage to produce a calibration signal for calibrating the Hall effect sensor circuit to drive the error voltage toward zero. The system may further include a feedback network that applies the calibration signal to the Hall effect sensor circuit so as to force the output of the first sample/hold circuit to match the reference voltage. The Hall effect sensor circuit may include four Hall effect sensors physically arranged and interconnected so that, in a first phase, their outputs combine to yield the magnetic field around the self-test inductor, and in a second phase, their outputs combine to yield the magnetic field around the input inductor. The four Hall effect sensors may be positioned such that external magnetic field contributions cancel when their outputs are combined.

A system for measuring a current includes a Hall effect sensor circuit configured to produce differential voltage outputs based on magnetic fields around a first inductor and a second inductor. An input and extraction circuit is configured to alternatingly output a differential voltage indicative of magnetic fields around the first inductor and the second inductor. An amplifier is configured to amplify the differential voltages output by the input and extraction circuit. A first sample/hold circuit is configured to sample output of the amplifier when that output is indicative of the magnetic field around the second inductor. An integrator circuit is configured to calibrate the Hall effect sensor circuit based upon on an error between the output sampled by the first sample/hold circuit and a reference voltage.

The system may further include a second sample/hold circuit configured to sample the output of the amplifier when that output is indicative of the magnetic field around the first inductor. A low-pass filter may be coupled to the output of the second sample/hold circuit to produce a measurement voltage proportional to a first current through the first inductor. The integrator circuit may include an analog subtraction stage configured to subtract the reference voltage from the output of the first sample/hold circuit to generate an error voltage representative of the error. The integrator circuit may further include an integrating element that integrates the error voltage to produce a calibration signal for calibrating the Hall effect sensor circuit to drive the error voltage toward zero. The system may further include a feedback network that applies the calibration signal to the Hall effect sensor circuit so as to force the output of the first sample/hold circuit to match the reference voltage. The Hall effect sensor circuit may include four Hall effect sensors physically arranged and interconnected so that, in a first phase, their outputs combine to yield the magnetic field around the second inductor, and in a second phase, their outputs combine to yield the magnetic field around the first inductor. The four Hall effect sensors may be positioned such that external magnetic field contributions cancel when their outputs are combined.

### BRIEF DESCRIPTION OF THE DRAWINGS

FIG. 1 is a block diagram of a first embodiment of an analog front-end for a Hall effect sensor circuit.

FIG. 2 is a diagram showing the relationship between the physical orientations of the individual Hall effect sensors within the Hall effect sensor circuit of FIG. 1 and the magnetic fields about the input inductor and self-test inductor, as well as the magnetic field of the Earth.

FIG. 3 is a block diagram of a second embodiment of an analog front-end for a Hall effect sensor circuit.

FIG. 4A is a schematic diagram of the signal accumulator of FIG. 3.

FIG. 4B is a timing diagram showing operation of the switches of the signal accumulator of FIG. 4A.

FIG. 5 is a schematic diagram of the reference accumulator of FIG. 3.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Note that in the following description, any resistor or resistance mentioned is a discrete device, unless stated otherwise, and is not simply an electrical lead between two points. Therefore, any resistor or resistance connected between two points has a higher resistance than a lead between those two points, and such resistor or resistance cannot be interpreted as a lead. Similarly, any capacitor or capacitance mentioned is a discrete device, unless stated otherwise, and is not a parasitic element, unless stated otherwise. Additionally, any inductor or inductance mentioned is a discrete device, unless stated otherwise, and is not a parasitic element, unless stated otherwise.

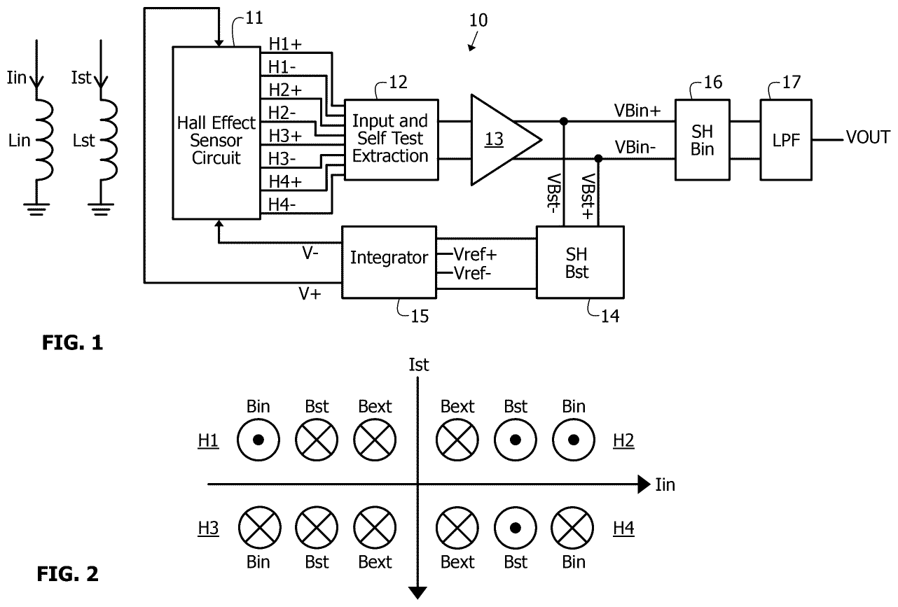

Now described with reference to FIG. 1 is an analog front-end 10 for a Hall effect sensor circuit 11.

An input current Iin to be measured flows through an inductor Lin, and a self-test current Iist flows through an inductor Lst. The Hall effect sensor circuit 11 produces differential voltages V+, V− based on the magnetic field B surrounding the inductors Lin and Lst.

An input and self-test extraction circuit 12 is connected to receive output from the Hall effect sensor circuit 11. As will be explained in detail below, the input and self-test extraction circuit 12 alternates its output of a differential voltage to represent either the magnetic field Bin surrounding the inductor Lin or the magnetic field Bst around the inductor Lst. This differential voltage is amplified by the amplifier 13, having a gain G. When the voltage output by the amplifier 13 represents the magnetic field Bst about the inductor Lst (the voltage in this instance being represented as VBst+, VBst−), the sample/hold circuit 14 samples and holds the amplified differential voltage; when the voltage output by the amplifier 13 represents the magnetic field Bin about the inductor Lin (the voltage in this instance being represented as VBin+, VBin−), the sample/hold circuit 16 samples and holds the amplified differential voltage.

Referring back to the case where the voltage VBst+, VBst− representing the magnetic field Bst about the inductor Lst is output by the amplifier 13 and sampled by the sample/hold circuit 14, the integrator 15 integrates this sampled voltage after subtracting a reference voltage, given as Vref+, Vref−. This integration effectively yields a differential voltage V+, V− that is proportional to the difference between the sampled voltage VBst+, VBst− and the reference voltages Vref+, Vref−. This differential voltage V+, V− is connected to the Hall effect sensor circuit 11 such that the input and output of the sample/hold circuit 14, via this feedback mechanism, match the reference voltages Vref+, Vref−. This mechanism enables calibration of the circuit 10 by compensating for the sensitivity of the Hell effect sensor circuit 11.

Stated differently, the integrator 15 produces an error voltage by subtracting Vref+, Vref− from the sampled voltage. This error voltage utilized in adjusting the Hall effect sensor circuit 11 to reach a point where the error is reduced substantially to zero, which means that the input/output of the sample/hold circuit 14 is equal to Vref+, Vref−.

As explained, when the voltage VBin+, VBin− representing the magnetic field Bin about the inductor Lin is output by the amplifier 13, the sample/hold circuit 16 samples that differential voltage. Subsequently, the sampled voltage VBin+, VBin− undergoes low-pass filtering via filter 17 to thereby produce an output voltage VOUT which is indicative of the input current Iin. As a result of the operation of the feedback loop, the output VOUT of the LPF 17 is (assuming the gain of the amplifier 13 to be unity) equal to the ratio of the voltage VBin to the voltage VBst, multiplied by the reference voltage Vref. Mathematically this is represented as:

$$VOUT = \frac{Vref}{VBst} \cdot VBin .$$

Thus, the gain to be applied the output voltage VOUT is solely that applied by the amplifier 13, independent of the sensitivity of the hall effect sensor circuit 11.

Turning now to FIG. 2, the operation of the input and self-test extraction circuit 12 is now described. The Hall effect sensor circuit 11 is comprised of four separate Hall effect sensors, labeled as H1, H2, H3 and H4. The physical placement of the individual Hall effect sensors H1-H4 provides for specific orientations relative to the magnetic fields as follows:

As seen from H1, the magnetic field Bin about the inductor Lin is directed out of the page, the magnetic field Bst about the inductor Lst is directed into the page, and the magnetic field Bext of the environment (e.g., the earth magnetic field) is directed into the page. Mathematically, this can be represented as:

$$BH 1 = Bin - Bst - Bext \qquad ( 1 )$$

As seen from H2, the magnetic field Bin is directed out of the page, the magnetic field Bst is directed out of the page, and the magnetic field Bext is directed into the page. Mathematically, this can be represented as:

$$BH 2 = Bin + Bst - Bext \qquad ( 2 )$$

As seen from H3, the magnetic field Bin is directed into the page, the magnetic field Bst is directed into the page, and the magnetic field Bext is directed into the page. Mathematically, this can be represented as:

$$BH 3 = - Bin - Bst - Bext \qquad ( 3 )$$

As seen from H4, the magnetic field Bin is directed into the page, the magnetic field Bst is directed out of the page, and the magnetic field Bext is directed into the page. Mathematically, this can be represented as:

$$BH 4 = - Bin + Bst - Bext \qquad ( 4 )$$

1 Equations (1), (2), (3), (4) can be combined to solve for the magnetic fields Bin and Bst and form the following two equations:

$$Bin = BH 1 + BH 2 - BH 3 - BH 4 \qquad ( 5 )$$

$$Bst = BH 2 + BH 4 - BH 1 - BH 3 \qquad ( 6 )$$

The function of the input and self-test extraction circuit 12 is therefore to interconnect the Hall effect sensors H1, H2, H3, and H4 so that the resultant output from the Hall effect sensor circuit 11 alternates between representing the magnetic field Bin of the inductor Lin and the magnetic field Bst of the inductor Lst. Each of these Hall effect sensors H1-H4 has first and second power supply inputs (connected to the outputs of integrator 15), as well as both positive and negative outputs.

In order to add the outputs of two Hall effect sensors, within the input and self-test extraction circuit 12, the positive outputs thereof are connected to one another, and the negative outputs thereof are connected to one another. Similarly, in order to subtract the output of one Hall effect sensor from another, the positive output of the first Hall effect sensor is connected to the negative output of the second Hall effect sensor, while the negative output of the first Hall effect sensor is connected to the positive output of the second Hall effect sensor.

According to this, in order for the input and self-test extraction circuit 12 to output Bin, the outputs of the Hall effect sensors H1, H2, H3, H4 are connected as described above to produce equation (5), and in order for the input and self-test extraction circuit 12 to output Bst, the outputs of the Hall effect sensors H1, H2, H3, H4 are connected as described above to produce equation (6).

This, in order for the input and self-test extraction circuit 12 to output the differential voltage VBst+, VBst− representative of the magnetic field Bst surrounding the self-test inductor Lst, the Hall effect sensors H1-H4 are connected as described above to produce equation (6), while in order for the input and self-test extraction 12 to output the differential voltage VBin+, VBin− representative of the magnetic field Bin surrounding the input inductor Lin (and thus, representative of the input current Iin), the Hall effect sensors H1-H4 are connected as described above to produce equation (5).

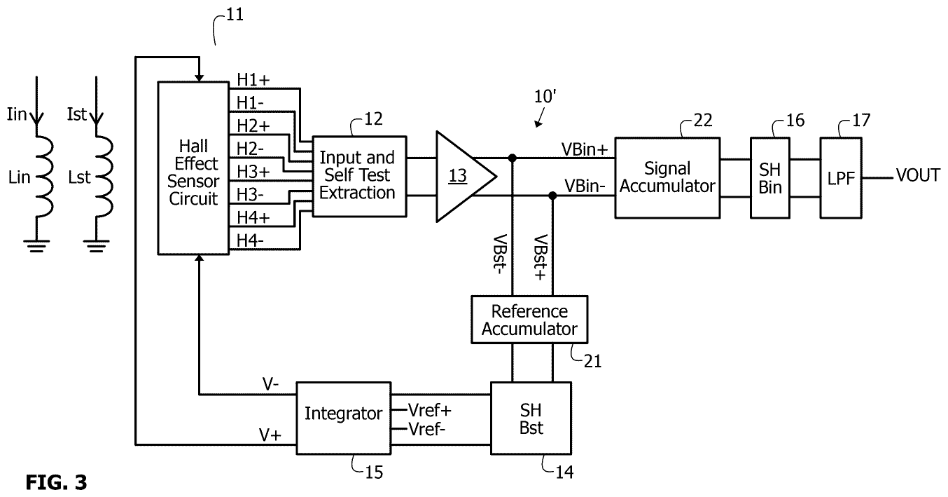

Another embodiment of an analog front-end 10′ for a Hall effect sensor circuit 11 is now described with reference to FIG. 3. Note in this embodiment, a reference accumulator 21 is coupled between the outputs of the amplifier 13 and the inputs of the sample/hold circuit 14, and a signal accumulator 22 is coupled between the outputs of the amplifier 13 and the inputs of the sample/hold circuit 16.

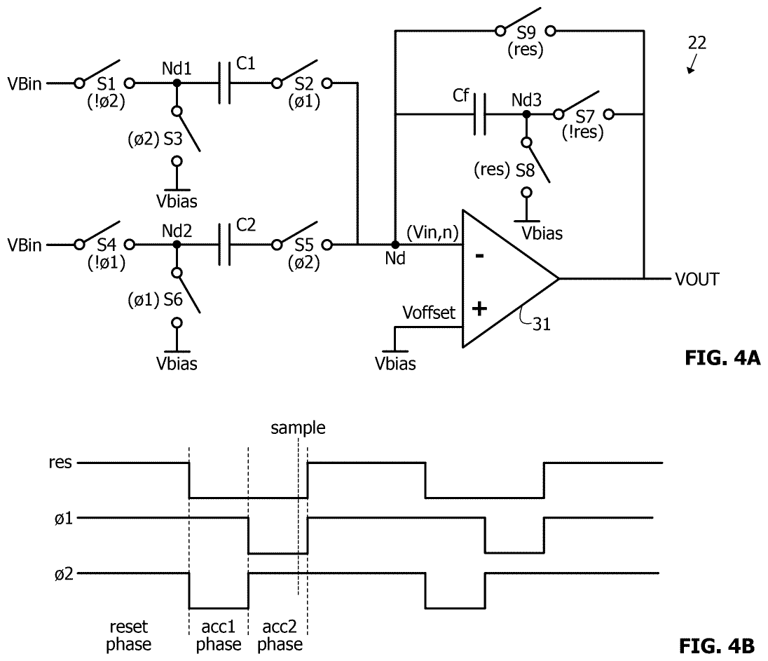

Turning now to FIG. 4A, the specific details of the signal accumulator 22 are now given, with the signal accumulator 22 being represented in single-ended form in this example, and therefore in this example, the voltage representing the magnetic field Bin about the inductor Lin is represented as VBin. The signal accumulator 22 includes an amplifier 31 having its non-inverting input connected to a bias voltage Vbias and its inverting input connected to node Nd. A switch S1 selectively couples the voltage VBin representing the magnetic field Bin about the inductor Lin to node Nd1, in response to the control signal !Ø2. A capacitor C1 is connected between node Nd1 and a first terminal of switch S2, which selectively couples capacitor C1 to node Nd in response to the control signal Ø1. A switch S3 selectively couples node Nd1 to Vbias, in response to the control signal Ø2. A switch S4 selectively couples the voltage VBin representing the magnetic field Bin about the inductor Lin to node Nd2, in response to the control signal !Ø1. A capacitor C2 is connected between node Nd2 and a first terminal of switch S5, which selectively couples capacitor C2 to node Nd in response to the control signal Ø2. A switch S6 selectively couples node Nd2 to Vbias, in response to the control signal Ø1.

A capacitor Cf is connected between nodes Nd and Nd3. A switch S7 selectively couples node Nd3 to the output of the amplifier 31, in response to the control signal !res. A switch S8 selectively couples node Nd3 to Vbias, in response to control signal res. A switch S9 selectively couples node Nd to the output of the amplifier 31, in response to the control signal res. The output voltage VOUT is produced at the output of the amplifier 31.

The operation of the signal accumulator 22 will now be described, with this operation serving to auto-zero the amplifier offset and remove latency resulting from sampling. Refer now to FIG. 4B, where it can be seen that operation proceeds through a reset phase, a first accumulation phase, and a second accumulation phase.

Initially, a reset phase is performed. As shown in FIG. 4B, during the reset phase, the control signal res is asserted, closing switches S8 and S9, and the control signals Ø1 and Ø2 are asserted, closing switches S2, S3, S5, and S6, with the remaining switches opened. This discharges capacitors C1, C2, and Cf, and shorts the inverting input and output of the amplifier 31 to one another.

Following the reset phase, the first accumulation phase begins. During this phase, the control signal Ø2 is deasserted (so its inverse !Ø2 is asserted), thereby closing switch S1 and passing the voltage VBin to node Nd1. Concurrently, the control signal Ø1 remains asserted (so its inverse !Ø1 is deasserted), leading to the continuation of the closure of switches S2 and S6. This results in capacitor C1 accumulating the voltage difference between VBin and Vbias via node Nd1. Since the voltage VBin as fed to switch S4 does not play a role in this first accumulation phase, switch S4 remains open, ensuring that voltage VBin is not connected to node Nd2. By the end of this first accumulation phase, the output voltage VOUT can be derived from the relationship:

$$( C 1 + Cf ) \cdot Voffset = C 1 \cdot ( Voffset - Vin , n - 1 ) + Cf \cdot ( Voffset - VOUT , n - 1 )$$

In this, Voffset is the offset of the amplifier 31 and Vin,n is the voltage at the inverting input of the amplifier 31.

This can be arranged to yield:

$$VOUT , n - 1 = ( - \frac{C 1}{C f} ) \cdot Vin , n - 1$$

Next, the second accumulation phase begins. During this phase, the control signal Ø1 is deasserted (so the control signal !Ø1 is asserted), closing switch S4, coupling voltage VBin to node Nd2. Concurrently, the control signal Ø2 is asserted (so the control signal !Ø2 is deasserted), closing switches S3 and S5. This results in capacitor C2 accumulating the voltage difference between VBin and the ground via node Nd2. The voltage VBin at switch S1 is not connected in this phase because switch S1 is opened due to the control signal !Ø2 being deasserted.

By the end of this second accumulation phase, the output voltage VOUT can be derived from the relationship:

$$Cf \cdot ( Voffset - VOUT , n - 1 ) + C 2 \cdot Voffset = C 2 \cdot ( Voffset - Vin , n ) + Cf \cdot ( Voffset - VOUT , n )$$

This can be rearranged to yield:

$$VOUT , n = ( - \frac{C 2}{C f} ) \cdot Vin , n + VOUT , n - 1$$

Substituting in the value of VOUT,n−1 from the previous phase yields:

$$VOUT , n = ( - \frac{C 1}{C f} ) \cdot Vin , n - 1 + ( - \frac{C 2}{C f} ) \cdot Vin , n$$

Note therefore that the result is that the offset Voffset has been canceled from VOUT through the accumulation phases.

This design for the signal accumulator 22 therefore cancels the offset inherent to switched-capacitor accumulator stages without introducing complexity. Moreover, this design eliminates the need to sample the input signal, eliminating concerns of latency and providing for immediate response times. Still further, the design avoids introducing additional components to the virtual ground of the amplifier 31. Note this design may be adapted to use a fully differential amplifier 31.

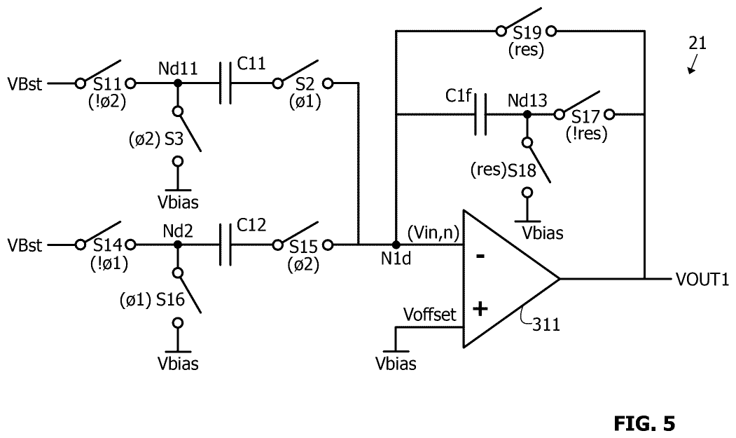

Turning now to FIG. 5, the specific details of the reference accumulator 21 are now given with the reference accumulator 21 being represented in single-ended form in this example, and therefore in this example, the voltage representing the magnetic field Bin about the inductor Lst is represented as VBst. The signal accumulator 21 includes an amplifier 311 having its non-inverting input connected to the bias voltage Vbias and its inverting input connected to node N1d. A switch S11 selectively couples the voltage VBst representing the magnetic field Bst about the inductor Lst to node Nd11, in response to the control signal !Ø2. A capacitor C11 is connected between node Nd11 and a first terminal of switch S12, which selectively couples capacitor C11 to node Nd in response to the control signal Ø1. A switch S13 selectively couples node Nd11 to Vbias, in response to the control signal Ø2. A switch S14 selectively couples the voltage VBst representing the magnetic field Bst about the inductor Lst to node Nd12, in response to the control signal !Ø1. A capacitor C12 is connected between node Nd12 and a first terminal of switch S15, which selectively couples capacitor C12 to node N1d in response to the control signal Ø2. A switch S16 selectively couples node Nd12 to Vbias, in response to the control signal Ø1.

A capacitor C1f is connected between nodes N1d and Nd13. A switch S17 selectively couples node Nd13 to the output of the amplifier 311, in response to the control signal !res. A switch S18 selectively couples node Nd13 to Vbias, in response to control signal res. A switch S19 selectively couples node N1d to the output of the amplifier 311, in response to the control signal res. The output voltage VOUT1 is produced at the output of the amplifier 311.

Operation of the reference accumulator 21 is the same as the signal accumulator 22, with this operation serving to auto-zero the amplifier offset and remove latency resulting from sampling. Refer back to FIG. 4B, where it can be seen that operation proceeds through a reset phase, a first accumulation phase, and a second accumulation phase.

During the reset phase, the control signal res is asserted, closing switches S18 and S19, and the control signals Ø1 and Ø2 are asserted, closing switches S12, S13, S15, and S16, with the remaining switches opened. This discharges capacitors C11, C12, and C1f, and shorts the inverting input and output of the amplifier 311 to one another.

Following the reset phase, the first accumulation phase begins. During this phase, the control signal Ø2 is deasserted (so its inverse !Ø2 is asserted), thereby closing switch S11 and directing the voltage VBst to node Nd11. Concurrently, the control signal Ø1 remains asserted (so its inverse !Ø1 is deasserted), leading to the continuation of the closure of switches S12 and S16. This results in capacitor C11 accumulating the voltage difference between VBst and Vbias via node Nd11. Since the voltage VBst at switch S14 does not play a role in this first accumulation phase, switch S14 remains open, ensuring that voltage VBst is not connected to node Nd12. By the end of this first accumulation phase, the output voltage VOUT1 can be derived from the relationship:

$$( C 1 + Cf ) \cdot Voffset = C 1 \cdot ( Voffset , Vin , n - 1 ) + Cf \cdot ( Voffset - VOUT 1 , n - 1 )$$

In this, Voffset is the offset of the amplifier 311 and Vin,n is the voltage at the inverting input of the amplifier 311.

This can be arranged to yield:

$$VOUT 1 , n - 1 = ( - \frac{C 1}{C f} ) \cdot Vin , n - 1$$

Next, the second accumulation phase begins. During this phase, the control signal Ø1 is deasserted (so the control signal !Ø1 is asserted), closing switch S14, coupling voltage VBst to node Nd12. Concurrently, the control signal Ø2 is asserted (so the control signal !Ø2 is deasserted), closing switches S13 and S15. This results in capacitor C12 accumulating the voltage difference between VBst and Vbias via node Nd12. The voltage VBst at switch S11 is not connected in this phase because switch S11 is opened due to the control signal !Ø2 being deasserted.

By the end of this second accumulation phase, the output voltage VOUT1 can be derived from the relationship:

$$Cf \cdot ( Voffset - VOUT 1 , n - 1 ) + C 2 \cdot Voffset = C 2 \cdot ( Voffset - Vin , n ) + Cf \cdot ( Voffset - VOUT 1 , n )$$

This can be rearranged to yield:

$$VOUT 1 , n = ( - \frac{C 2}{C f} ) \cdot Vin , n + VOUT 1 , n - 1$$

Substituting in the value of VOUT1,n−1 from the previous phase yields:

$$VOUT 1 , n = ( - \frac{C 1}{C f} ) \cdot Vin , n - 1 + ( - \frac{C 2}{C f} ) \cdot Vin , n$$

Note therefore that the result is that the offset Voffset has been canceled from VOUT1 through the accumulation phases. This design may be adapted to use a fully differential amplifier 311.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A method of measuring an input current using an analog front-end, comprising:
driving an input inductor with the input current to produce an input magnetic field;
driving a self-test inductor with a known self-test current to produce a self-test magnetic field;
alternately extracting differential voltages proportional to the input magnetic field and the self-test magnetic field via a Hall effect sensor circuit and an extraction circuit;
sampling and holding the differential voltage proportional to the self-test magnetic field;
generating an error voltage by subtracting a reference voltage from the held differential voltage proportional to the self-test magnetic field;
integrating the error voltage over time to produce a calibration signal; and
calibrating the Hall effect sensor circuit using the calibration signal to drive the error voltage toward zero.

2. The method of claim 1, further comprising:
sampling and holding the differential voltage proportional to the input magnetic field; and
filtering the held differential voltage proportional to the input magnetic field to thereby produce an output voltage proportional to the input current.

3. The method of claim 1, wherein integrating the error voltage comprises integrating the error voltage in an analog integrator.

4. The method of claim 1, wherein calibrating the Hall effect sensor circuit forces the held differential voltage proportional to the self-test magnetic field to match the reference voltage.

5. The method of claim 1, wherein alternately extracting the differential voltages comprises reconfiguring interconnections of four Hall effect sensors of the Hall effect sensor circuit so that, in a first phase, their outputs combine to yield the self-test magnetic field, and in a second phase, their outputs combine to yield the input magnetic field.

6. The method of claim 5, wherein alternately extracting the differential voltages further comprises positioning the four Hall effect sensors such that external magnetic field contributions cancel when their outputs are combined during the extraction.

7. A system for measuring an input current, comprising:
a Hall effect sensor circuit configured to produce differential voltage outputs based on magnetic fields around an input inductor and a self-test inductor;
an input and self-test extraction circuit configured to alternatingly output a differential voltage indicative of magnetic fields around the input inductor and the self-test inductor;
an amplifier configured to amplify the differential voltages output by the input and self-test extraction circuit;
a first sample/hold circuit configured to sample output of the amplifier when that output is indicative of the magnetic field around the self-test inductor; and
an integrator circuit configured to calibrate the Hall effect sensor circuit based upon on an error between the output sampled by the first sample/hold circuit and a reference voltage.

8. The system of claim 7, further comprising:
a second sample/hold circuit configured to sample the output of the amplifier when that output is indicative of the magnetic field around the input inductor; and
a low-pass filter coupled to the output of the second sample/hold circuit to produce a measurement voltage proportional to the input current.

9. The system of claim 7, wherein the integrator circuit comprises an analog subtraction stage configured to subtract the reference voltage from the output of the first sample/hold circuit to generate an error voltage representative of the error.

10. The system of claim 9, wherein the integrator circuit further comprises an integrating element that integrates the error voltage to produce a calibration signal for calibrating the Hall effect sensor circuit to drive the error voltage toward zero.

11. The system of claim 10, further comprising a feedback network that applies the calibration signal to the Hall effect sensor circuit so as to force the output of the first sample/hold circuit to match the reference voltage.

12. The system of claim 7, wherein the Hall effect sensor circuit comprises four Hall effect sensors physically arranged and interconnected so that, in a first phase, their outputs combine to yield the magnetic field around the self-test inductor, and in a second phase, their outputs combine to yield the magnetic field around the input inductor.

13. The system of claim 12, wherein the four Hall effect sensors are positioned such that external magnetic field contributions cancel when their outputs are combined.

14. A system for measuring a current, comprising:
a Hall effect sensor circuit configured to produce differential voltage outputs based on magnetic fields around a first inductor and a second inductor;
an input and extraction circuit configured to alternatingly output a differential voltage indicative of magnetic fields around the first inductor and the second inductor;
an amplifier configured to amplify the differential voltages output by the input and extraction circuit;
a first sample/hold circuit configured to sample output of the amplifier when that output is indicative of the magnetic field around the second inductor; and
an integrator circuit configured to calibrate the Hall effect sensor circuit based upon on an error between the output sampled by the first sample/hold circuit and a reference voltage.

15. The system of claim 14, further comprising:
a second sample/hold circuit configured to sample the output of the amplifier when that output is indicative of the magnetic field around the first inductor; and
a low-pass filter coupled to the output of the second sample/hold circuit to produce a measurement voltage proportional to a first current through the first inductor.

16. The system of claim 14, wherein the integrator circuit comprises an analog subtraction stage configured to subtract the reference voltage from the output of the first sample/hold circuit to generate an error voltage representative of the error.

17. The system of claim 16, wherein the integrator circuit further comprises an integrating element that integrates the error voltage to produce a calibration signal for calibrating the Hall effect sensor circuit to drive the error voltage toward zero.

18. The system of claim 17, further comprising a feedback network that applies the calibration signal to the Hall effect sensor circuit so as to force the output of the first sample/hold circuit to match the reference voltage.

19. The system of claim 14, wherein the Hall effect sensor circuit comprises four Hall effect sensors physically arranged and interconnected so that, in a first phase, their outputs combine to yield the magnetic field around the second inductor, and in a second phase, their outputs combine to yield the magnetic field around the first inductor.

20. The system of claim 19, wherein the four Hall effect sensors are positioned such that external magnetic field contributions cancel when their outputs are combined.
